(19) United States
(12) Patent Application Publication
(10) Pub. No.: US 2021/0020821 A1
(43) Pub. Date: Jan. 21, 2021

(54) Multifunctional Quantum Node Device and Methods

(71) Applicant: Naval Information Warfare Center Pacific, San Diego, CA (US)

(72) Inventors: Osama M. Nayfeh, San Diego, CA (US); Anna M. Leese de Escobar, Encinitas, CA (US); Kenneth S. Simonsen, San Diego, CA (US)

(73) Assignee: United States of America as represented by Secretary of the Navy, San Diego, CA (US)

(21) Appl. No.: 16/513,387

(22) Filed: Jul. 16, 2019

(51) Int. Cl. H01L 39/10; H01L 39/02; H01L 39/12; H01L 39/22; H01L 39/24; G02B 6/42; G06N 10/00

(52) U.S. Cl. CPC H01L 39/10; H01L 39/025; H01L 39/125; G06N 10/00; H01L 39/2493; G02B 6/4202; H01L 39/223

(57) ABSTRACT

A multifunctional quantum node device involving a semiconductor vacancy qubit structure, a superconductor quantum memory nanowire coupled with a spin state of the semiconductor vacancy qubit structure, and a superconductor qubit logic circuit coupled with the superconductor quantum memory nanowire and the semiconductor vacancy qubit structure, whereby the device is a hybrid device operable as an interface for at least one of computing and quantum-entangled networking.

### FEDERALLY-SPONSORED RESEARCH AND DEVELOPMENT

The United States Government has ownership rights in the subject matter of the present disclosure. Licensing inquiries may be directed to Office of Research and Technical Applications, Naval Information Warfare Center, Pacific, Code 72120, San Diego, Calif., 92152; telephone (619) 553-5118; email: ssc_pac_t2@navy.mil. Reference Navy Case No. 104095.

### TECHNICAL FIELD

The present disclosure technically relates to quantum computing interfaces.

### BACKGROUND OF THE INVENTION

In the related art, a microwave photonic scheme, e.g., a broadband scheme, involving a multi-resonator quantum memory-interface has been researched. This scheme involves a system of mini-resonators, strongly interacting with a common broadband resonator, coupled with an external waveguide. An impedance-matched quantum storage in this scheme is implemented via controllable frequency tuning of the mini-resonators and coupling of the common broadband resonator with the external waveguide.

Also, in the related art, solid-state spins, such as “nitrogen-vacancy (NV) center,” are considered as platforms for large-scale quantum networks. Despite the optical interface of an NV center system, a major attenuation of such system's zero-phonon-line photon in an optical fiber prevents the network from being significantly extended. A telecom-wavelength photon interface is considered for reducing the photon loss in transporting quantum information, wherein a scheme for coupling telecom photons to NV center ensembles mediated by a rare-earth doped crystal.

Additionally, in the related art, trapped atomic ions are a leading platform for quantum information networks, with long-lived identical qubit memories that can be locally entangled through their Coulomb interaction and remotely entangled through photonic channels. However, performing both local and remote operations in a single node of a quantum network requires extreme isolation between spectator qubit memories and qubits associated with the photonic interface. Isolation by co-trapping 171Yb+ and 138Ba+ qubits has been proposed.

Challenges experienced in the related art include, for example, a major attenuation of the zero-phonon-line photon in an optical fiber which prevents a network from being significantly extended and a requirement for extreme isolation between spectator qubit memories and qubits associated with the photonic interface. Therefore, a need exists for interfacing quantum memory to the external world and for enabling operation at a single spin and/or at a single photon level.

### SUMMARY OF INVENTION

To address at least the needs in the related art, a multifunctional quantum node device comprises a semiconductor vacancy qubit structure, a superconductor quantum memory nanowire coupled with a spin state of the semiconductor vacancy qubit structure, and a superconductor qubit logic circuit coupled with the superconductor quantum memory nanowire and the semiconductor vacancy qubit structure, whereby the device is a hybrid device operable as an interface for at least one of computing and quantum-entangled networking, in accordance with an embodiment of the present disclosure.

### BRIEF DESCRIPTION OF THE DRAWING(S)

The above, and other, aspects, features, and benefits of several embodiments of the present disclosure are further understood from the following Detailed Description of the Invention as presented in conjunction with the following several figures of the Drawing.

FIG. 1A is a schematic diagram illustrating, in a perspective view, a cryo-magneto-optical probe station system, utilizing a multifunctional quantum node device, in accordance with an embodiment of the present disclosure.

FIG. 1B is a schematic diagram illustrating, in a perspective view, a multifunctional quantum node device, as utilized in a cryo-magneto-optical probe station system, in accordance with an embodiment of the present disclosure.

FIG. 2A is a scanning electron micrograph (38536× magnification) illustrating a region of the superconductor qubit logic circuit, comprising a pair of outer material layers and an inner material layer disposed between the pair of outer material layers, in accordance with an embodiment of the present disclosure.

FIG. 2B is a scanning electron micrograph (38531× magnification) illustrating a region of the superconductor qubit logic circuit, comprising a pair of outer material layers and an inner material layer disposed between the pair of outer material layers, in accordance with an embodiment of the present disclosure.

FIG. 2C scanning electron micrograph (38522× magnification) illustrating a region of the superconductor qubit logic circuit, comprising a pair of outer material layers and an inner material layer disposed between the pair of outer material layers, in accordance with an embodiment of the present disclosure.

FIG. 2D is a scanning electron micrograph (1205× magnification) illustrating a region of the superconductor qubit logic circuit, comprising a pair of outer material layers and an inner material layer disposed between the pair of outer material layers, in accordance with an embodiment of the present disclosure.

FIG. 3 is a schematic diagram illustrating a relationship established by a physical coupling between a semiconductor vacancy qubit structure and a superconductor quantum memory nanowire, as implementable in a multifunctional quantum node device, the semiconductor vacancy qubit structure having an energy level as a function of magnetic field, shown from a ground state to an excited state, and the superconductor quantum memory nanowire, comprising some example rare-earth ions, having an energy level distribution, in accordance with an embodiment of the present disclosure.

FIG. 4 is a flow diagram illustrating a method of fabricating a multifunctional quantum node device, in accordance with an embodiment of the present disclosure.

FIG. 5 is a flow diagram illustrating a method of interfacing, for at least one of computing and networking, by way of a multifunctional quantum node device, in accordance with an embodiment of the present disclosure.

FIG. 6A is an image of an example experimental instantiation of a multifunctional quantum node device.

FIG. 6B is an image of a semiconductor spin qubit embodiment of a semiconductor vacancy qubit structure.

Corresponding reference numerals or characters indicate corresponding components throughout the several figures of the Drawing. Elements in the several figures are illustrated for simplicity and clarity and have not necessarily been drawn to scale. For example, the dimensions of some of the elements in the figures may be emphasized relative to other elements for facilitating understanding of the various presently disclosed embodiments. Also, common, but well-understood, elements that are useful or necessary in commercially feasible embodiment are often not depicted in order to facilitate a less obstructed view of these various embodiments of the present disclosure.

### DETAILED DESCRIPTION OF THE EMBODIMENT(S)

In general, the devices and methods of the present disclosure involve a multifunctional quantum node that is based on a hybrid configuration using rare-earth ions, superconductors, and semiconductor vacancies. The devices and methods of the present disclosure address challenges in the related art by coupling energy levels of the hybrid quantum technologies in the hybrid configuration operable as a quantum node, e.g., a quantum processor or network node, thereby improving quantum memory at a single nuclear spin and/or a photonic level.

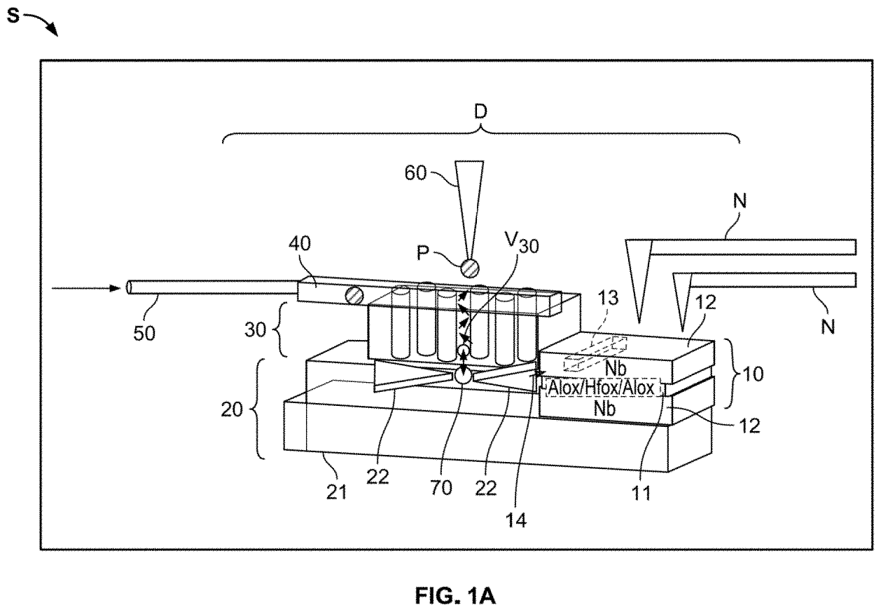

Referring to FIG. 1A, this schematic diagram illustrates in a perspective view, a cryo-magneto-optical probe station system S, utilizing a multifunctional quantum node device D, by example only, in accordance with an embodiment of the present disclosure. The multifunctional quantum node device D is configured for many other computing and networking, e.g., quantum-entangled networking, implementations, such as a stand-alone quantum computer processor or a multi-node quantum network, e.g., a quantum internet, wherein the quantum nodes are quantum-entangled. The device D, comprising the quantum nodes, could be fabricated entirely in relation to, or on, at least one of a single chip and a multi-chip platform; and the device D can be housed in a cryo-magneto-optical station located on various relevant platforms. A detailed description of the device D follows in relation to FIG. 1B.

Referring to FIG. 1B, this schematic diagram illustrates in a perspective view, a multifunctional quantum node device D, as utilized in a cryo-magneto-optical probe station system S, in accordance with an embodiment of the present disclosure. The multifunctional quantum node device D comprises: a semiconductor vacancy qubit structure 30; a superconductor quantum memory nanowire 20 coupled with a spin state of the semiconductor vacancy qubit structure 30; and a superconductor qubit logic circuit 10 coupled with the superconductor quantum memory nanowire 20 and the semiconductor vacancy qubit structure 30, whereby the device D is a hybrid device operable as an interface for at least one of computing and quantum-entangled networking.

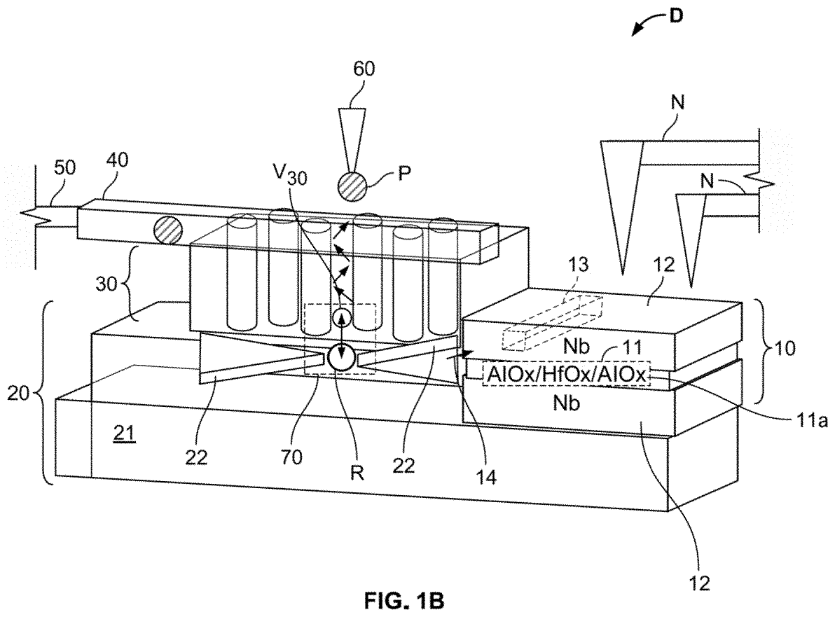

Still referring to FIG. 1B, The superconductor qubit logic circuit 10 comprises at least one of a superconductor-based vacancy qubit, a semiconductor-based vacancy qubit, and a qubit logic circuit. The superconductor qubit logic circuit 10 comprises: a pair of outer material layers 12; and an inner material layer 11 disposed between the pair of outer material layers 12. The outer material layers 12 comprise niobium (Nb); and the inner material layer 11 comprises at least one of aluminum oxide (AlOₓ) and hafnium oxide (HfO_{y}), wherein x=an integer, and y=an integer, wherein x and y are determined by the process and a desired vacancy configuration, and wherein x and y are typically less than the integer two (2) to ensure a non-stoichiometric nature and a high purity of the desired vacancy. The inner material layer 11 comprises at least one of an insulator material, a semiconductor material, a ferro-electric material, and a ferro-magnetic materials, wherein the inner material layer 11 is one of doped and undoped, and wherein, if doped, the inner material layer 11 comprises a dopant, the dopant comprising an ionic species depending on at least one of a desired coherence length and a desired functionality of the barrier. The qubit logic circuit of the superconductor qubit logic circuit 10 comprises at least one of superconductor-barrier-ionic-barrier-superconductor (SBIBS) device and a Josephson junction qubit logic structure, by examples only. Region 13 of the superconductor qubit logic circuit 10 is described further in relation to FIGS. 2A-2C.

Still referring to FIG. 1B, the superconductor quantum memory nanowire 20 is optically active; and the superconductor quantum memory nanowire 20 comprises: a superconductor material 21; and at least one rare-earth ion doping the superconductor material in nanowire regions 22. The at least one rare-earth ion dopes the superconductor material 21 by embedding the nanowire regions 22, by example only. The at least one rare-earth ion is selectable for any specific implementation and comprises at least one of: cerium (Ce), dysprosium (Dy), erbium (Er), europium (Eu), gadolinium (Gd), holmium (Ho), lanthanum (La), lutetium (Lu), neodymium (Nd), e.g., Nd³⁺, praseodymium (Pr), promethium (Pm), samarium (Sm), scandium (Sc), terbium (Tb), thulium (Tm), ytterbium (Yb), and yttrium (Y). The desired doping levels of the at least one rare-earth ion are selected to enable the proper ion-to-ion separation when an ensemble is created so as to not result in quenching. The ionic concentration can approach the single ion level per device when a single photon or single ion activity is required for implementation of the quantum protocol. In addition to rare-earth-ions, embodiments of the present disclosure may include transition element ions, such as at least one of chromium 3+(Cr³⁺) and any other ion that provides useful spin activity, e.g., a phosphorus (K) ion. The at least one rare-earth ion is selectable for any specific implementation, e.g., depending on at least one of a functionality, a desired operating regime, a desired electron/nuclear spin configuration, an entanglement type, and a desired operating wavelength.

Still referring to FIG. 1B, the semiconductor vacancy qubit structure 30 comprises at least one of silicon carbide (SiC), diamond (C), and any appropriate semiconductor material. The device D further comprises: a photonic crystal waveguide 40; and a superconducting nanowire photodetector 50 coupled with the photonic crystal waveguide 40, the superconducting nanowire photodetector 50 configured to detect photons, whereby the device D is interfaceable in at least one of a single nuclear spin 70 and a single photon P by way of a confocal input/output (I/O) 60 and detection of the photons by the superconducting nanowire photodetector 50. The device D is operable in a cryo-magneto-optical probe station system, by example only. In operation of the device D, the rare-earth ion R in the regions 22 of the superconductor quantum memory nanowire 20 either migrate to fill, or optically couple with, by resonant matching of the energy levels by the degree of Stark-splitting or Zeeman-splitting, vacancies V₃₀ in the semiconductor vacancy qubit structure 30, thereby activating superconductor qubit logic circuit 10, e.g., as shown by arrow 14, and thereby enabling nodal operation of the device D.

Referring to FIG. 2A, this scanning electron micrograph (38536× magnification) illustrates a region 13 of the superconductor qubit logic circuit 10, comprising a pair of outer material layers 12 and an inner material layer 11 disposed between the pair of outer material layers 12, in accordance with an embodiment of the present disclosure. By example only, the pair of outer material layers 12 comprise a silicon dioxide or silica (SiO₂) substrate doped with a rare-earth ion, e.g., Nb, wherein the rare-earth ion either migrates from each outer material layer 12 toward the inner material layer 11 or a spin dependent optical emission is coupled between each outer material layer 12 and the inner material layer 11, whereby a closed-link structure 15 is formed.

Referring to FIG. 2B, this scanning electron micrograph (38531× magnification) illustrates a region 13 of the superconductor qubit logic circuit 10, comprising a pair of outer material layers 12 and an inner material layer 11 disposed between the pair of outer material layers 12, in accordance with an embodiment of the present disclosure. By example only, the pair of outer material layers 12 comprise a silicon dioxide or SiO₂ substrate doped with a rare-earth ion, e.g., Nb, wherein the rare-earth ion either migrates from each outer material layer 12 toward the inner material layer 11 or a spin dependent optical emission is coupled between each outer material layer 12 and the inner material layer 11, e.g., to fill a vacancy Vio, whereby a closed-link structure 15 is formed.

Referring to FIG. 2C, this scanning electron micrograph (38522× magnification) illustrates a region 13 of the superconductor qubit logic circuit 10, comprising a pair of outer material layers 12 and an inner material layer 11 disposed between the pair of outer material layers 12, in accordance with an embodiment of the present disclosure. By example only, the pair of outer material layers 12 comprise a silicon dioxide or SiO₂ substrate doped with a rare-earth ion, e.g., Nb, wherein the rare-earth ion either migrates from each outer material layer 12 toward the inner material layer 11 or a spin dependent optical emission is coupled between each outer material layer 12 and the inner material layer 11, whereby an open-link structure 16 is formed.

Referring to FIG. 2D, this scanning electron micrograph (1205× magnification) illustrates a region 13 of the superconductor qubit logic circuit 10, comprising a pair of outer material layers 12 and an inner material layer 11 disposed between the pair of outer material layers 12, in accordance with an embodiment of the present disclosure. By example only, the pair of outer material layers 12 comprise a silicon dioxide or SiO₂ substrate doped with a rare-earth ion, e.g., Nb, wherein the rare-earth ion either migrates from each outer material layer 12 toward the inner material layer 11 or a spin dependent optical emission is coupled between each outer material layer 12 and the inner material layer 11, whereby an open-link structure 16 is formed.

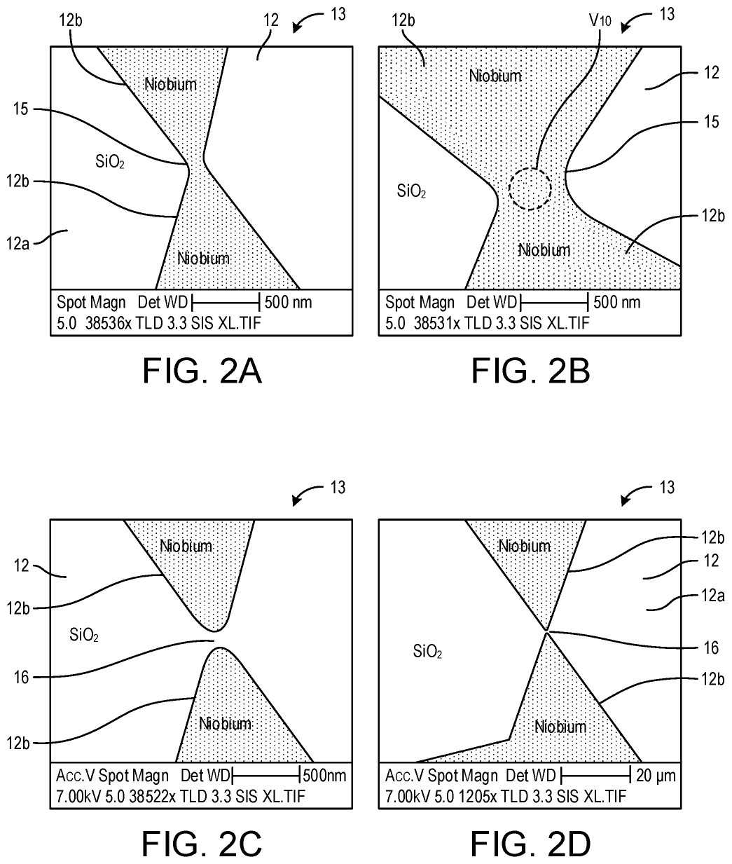

Referring to FIG. 3, this schematic diagram illustrates a relationship established by a physical coupling C between a semiconductor vacancy qubit structure 30 and a superconductor quantum memory nanowire 20, as implementable in a multifunctional quantum node device D, the semiconductor vacancy qubit structure 30 having an energy level as a function of magnetic field, shown from a ground state to an excited state, and the superconductor quantum memory nanowire 20, comprising some example rare-earth ions, having an energy level distribution, in accordance with an embodiment of the present disclosure. By example only, photonic activity is pumped at 808 nm and emitted at 1064 nm.

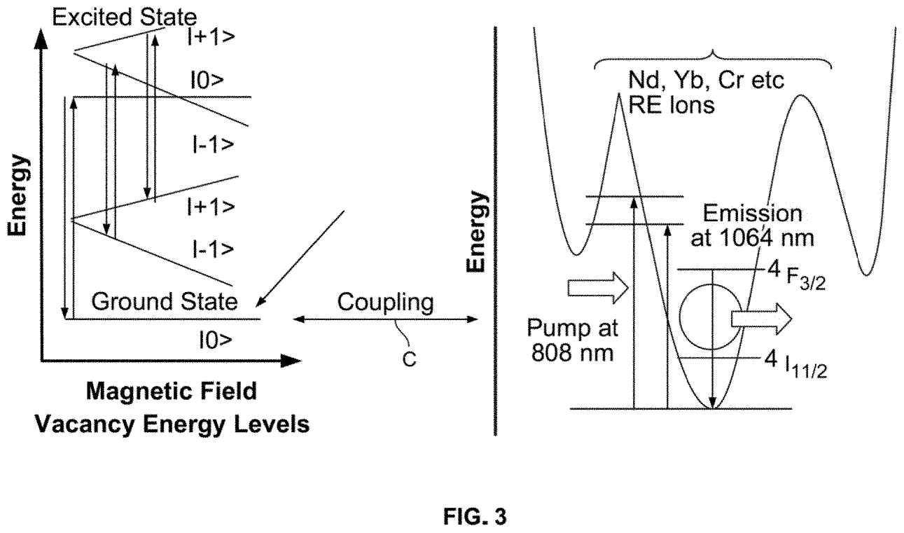

Referring to FIG. 4, this flow diagram illustrates a method M1 of fabricating a multifunctional quantum node device D comprises: providing a semiconductor vacancy qubit structure 30, as indicated by block 401; providing a superconductor quantum memory nanowire 20 coupled with a spin state of the semiconductor vacancy qubit structure 30, as indicated by block 402; and providing a superconductor qubit logic circuit 10 coupled with the superconductor quantum memory nanowire 20 and the semiconductor vacancy qubit structure 30, as indicated by block 403, whereby the device D is a hybrid device operable as an interface for at least one of computing and quantum-entangled networking, in accordance with an embodiment of the present disclosure.

Still referring to FIG. 4, in the method M1, providing the semiconductor vacancy qubit structure 30 comprises providing at least one of silicon carbide (SiC), diamond (C), and any semiconductor material, e.g., an appropriate semiconductor material for a desired implementation, providing the superconductor qubit logic circuit 10 comprises providing at least one of a semiconductor-based vacancy qubit and a qubit logic circuit, and providing the qubit logic circuit comprises providing at least one of a superconductor-barrier-ionic-barrier-superconductor SBIBS device and a Josephson junction qubit logic structure. Providing the superconductor quantum memory nanowire 20 comprises providing the superconductor quantum memory nanowire 20 as optically active. Providing the superconductor quantum memory nanowire 20 comprises providing a superconductor material 21 and providing at least one rare-earth ion R doping the superconductor material 21.

Still referring to FIG. 4, in the method M1, providing the at least one rare-earth ion R comprises doping the superconductor material 21 by embedding, providing the at least one rare-earth ion R comprises selecting the at least one rare-earth ion R for any specific implementation, and providing the at least one rare-earth ion R comprises providing at least one of: Ce, Dy, Er, Eu, Gd, Ho, La, Lu, Nd, Pr, Pm, Sm, Sc, Tb, Tm, Yb, and Y.

Still referring to FIG. 4, in the method M1, providing the qubit logic circuit comprises: providing a pair of outer material layers 12; and providing an inner material layer 11 disposed between the pair of outer material layers 12. Providing the outer material layers 12 comprises providing SiO₂ 12a doped with Nb 12b. Providing the inner material layer 11 comprises providing SiO₂ 12a doped with at least one dopant 11a of aluminum oxide (AlOₓ) and hafnium oxide (HfO_{y}), wherein x=an integer, and y=an integer.

Still referring to FIG. 4, the method M1 further comprises: providing a photonic crystal waveguide 40; and providing a superconducting nanowire photodetector 50 coupled with the photonic crystal waveguide 40, the superconducting nanowire photodetector 50 configured to detect photons, whereby the device D is interfaceable in at least one of a single nuclear spin 70 and a single photon P by way of a confocal input/output (I/O) 60 and detection of the photons by the superconducting nanowire photodetector 50. The device D is operable in a cryo-magneto-optical probe station system S. Providing the superconductor qubit logic circuit 10 comprises providing one of an open-link structure and a closed-link structure. Providing the at least one rare-earth ion R comprises selecting the at least one rare-earth ion R depending on at least one of functionality, desired operating regime, and desired operating wavelength.

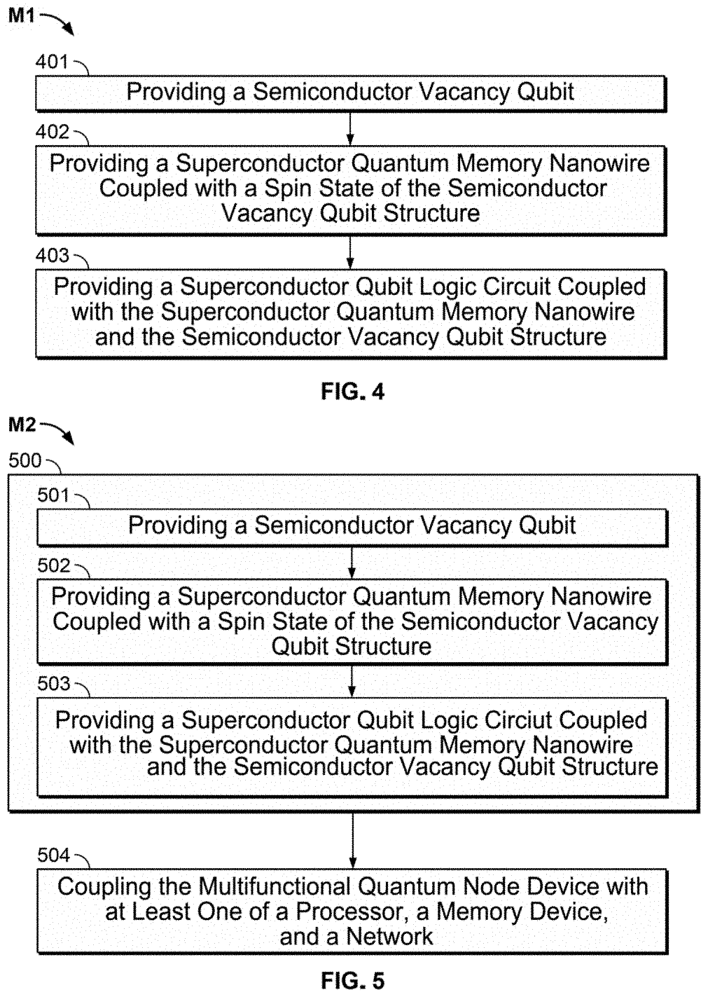

Referring to FIG. 5, this flow diagram illustrates a method M2 of interfacing, for at least one of computing and networking, by way of a multifunctional quantum node device D, comprising: providing a multifunctional quantum node device D, as indicated by block 500, providing the multifunctional quantum node device D comprising: providing a semiconductor vacancy qubit structure 30, as indicated by block 501; providing a superconductor quantum memory nanowire 20 coupled with a spin state of the semiconductor vacancy qubit structure 30, as indicated by block 502; and providing a superconductor qubit logic circuit 10 coupled with the superconductor quantum memory nanowire 20 and the semiconductor vacancy qubit structure 30, as indicated by block 503, whereby the device D is a hybrid device operable as an interface for at least one of computing and quantum-entangled networking; and coupling the multifunctional quantum node device D with at least one of a processor, a memory device, and a network N, as indicated by block 504, in accordance with an embodiment of the present disclosure.

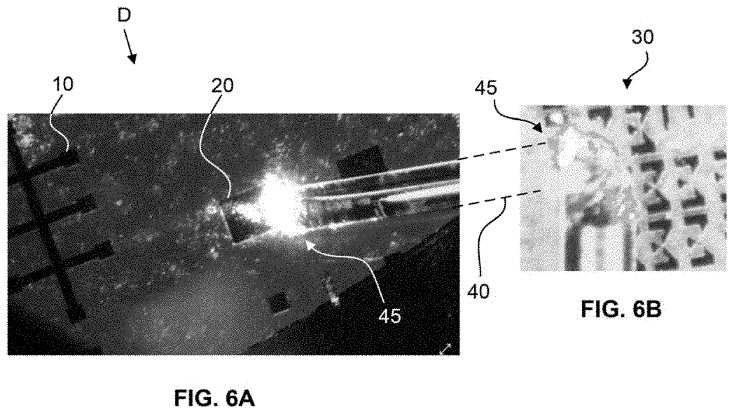

FIG. 6A is an image of an example experimental instantiation of the multifunctional quantum node device D that comprises an embodiment of the superconductor qubit logic circuit 10 that is made of Nb. The embodiment of the multifunctional quantum node device D shown in FIG. 6A also comprises an Nd:Nb embodiment of the superconductor quantum memory nanowire 20. FIG. 6B shows a semiconductor spin qubit embodiment of the semiconductor vacancy qubit structure 30. As shown in FIGS. 6A and 6B, the semiconductor vacancy qubit structure 30 and the superconductor quantum memory nanowire 20 are optically coupled via an embodiment of the photonic crystal waveguide 40 as evidences by the glowing regions 45.

It is to be understood that many additional changes in the details, materials, steps, and arrangement of parts, which have been herein described and illustrated to explain the nature of the invention, may be made by those skilled in the art within the principle and scope of the invention as expressed in the appended claims.

What is claimed:

1. A multifunctional quantum node device, comprising:
a semiconductor vacancy qubit structure;
a superconductor quantum memory nanowire coupled with a spin state of the semiconductor vacancy qubit structure; and
a superconductor qubit logic circuit coupled with the superconductor quantum memory nanowire and the semiconductor vacancy qubit structure,
whereby the device is a hybrid device operable as an interface for at least one of computing and quantum-entangled networking.

2. The device of claim 1,
wherein the semiconductor vacancy qubit structure comprises at least one of silicon carbide (SiC), diamond (C), and any semiconductor material,
wherein the superconductor qubit logic circuit comprises at least one of a semiconductor-based vacancy qubit and a qubit logic circuit, and
wherein the qubit logic circuit comprises at least one of a superconductor-barrier-ionic-barrier-superconductor (SBIBS) device and a Josephson junction qubit logic structure.

3. The device of claim 1,
wherein the superconductor quantum memory nanowire is optically active, and
wherein the superconductor quantum memory nanowire comprises:
a superconductor material; and
at least one rare-earth ion doping the superconductor material.

4. The device of claim 3,
wherein the at least one rare-earth ion dopes the superconductor material by embedding,
wherein the at least one rare-earth ion is selectable for any specific implementation, and
wherein the at least one rare-earth ion comprises at least one of: cerium (Ce), dysprosium (Dy), erbium (Er), europium (Eu), gadolinium (Gd), holmium (Ho), lanthanum (La), lutetium (Lu), neodymium (Nd), praseodymium (Pr), promethium (Pm), samarium (Sm), scandium (Sc), terbium (Tb), thulium (Tm), ytterbium (Yb), and yttrium (Y).

5. The device of claim 2, wherein the qubit logic circuit comprises:
a pair of outer material layers; and
an inner material layer disposed between the pair of outer material layers.

6. The device of claim 5,
wherein the outer material layers comprise silica (SiO₂) doped with niobium (Nb), and
wherein the inner material layer comprises SiO₂ doped with at least one of aluminum oxide (AlOₓ) and hafnium oxide (HfO_{y}), wherein x=an integer, and y=an integer.

7. The device of claim 1, further comprising:
a photonic crystal waveguide; and
a superconducting nanowire photodetector coupled with the photonic crystal waveguide, the superconducting nanowire photodetector configured to detect photons,
whereby the device is interfaceable in at least one of a single nuclear spin and a single photon by way of a confocal input/output (I/O) and detection of the photons by the superconducting nanowire photodetector.

8. The device of claim 1, wherein the device is operable in a cryo-magneto-optical probe station system.

9. The device of claim 1, wherein the superconductor qubit logic circuit comprises one of an open-link structure and a closed-link structure.

10. The device of claim 4, wherein the at least one rare-earth ion is selectable depending on at least one of functionality, desired operating regime, and desired operating wavelength.

11. A method of fabricating a multifunctional quantum node device, comprising:
providing a semiconductor vacancy qubit structure;
providing a superconductor quantum memory nanowire coupled with a spin state of the semiconductor vacancy qubit structure; and
providing a superconductor qubit logic circuit coupled with the superconductor quantum memory nanowire and the semiconductor vacancy qubit structure,
whereby the device is a hybrid device operable as an interface for at least one of computing and quantum-entangled networking.

12. The method of claim 11,
wherein providing the semiconductor vacancy qubit structure comprises providing at least one of silicon carbide (SiC), diamond (C), and any semiconductor material
wherein providing the superconductor qubit logic circuit comprises providing at least one of a semiconductor-based vacancy qubit and a qubit logic circuit, and
wherein providing the qubit logic circuit comprises providing at least one of a superconductor-barrier-ionic-barrier-superconductor (SBIBS) device and a Josephson junction qubit logic structure.

13. The method of claim 11,
wherein providing the superconductor quantum memory nanowire comprises providing the superconductor quantum memory nanowire as optically active, and
wherein providing the superconductor quantum memory nanowire comprises:
providing a superconductor material; and
providing at least one rare-earth ion doping the superconductor material.

14. The method of claim 13,
wherein providing the at least one rare-earth ion comprises doping the superconductor material by embedding,
wherein providing the at least one rare-earth ion comprises selecting the at least one rare-earth ion for any specific implementation, and
wherein providing the at least one rare-earth ion comprises providing at least one of: cerium (Ce), dysprosium (Dy), erbium (Er), europium (Eu), gadolinium (Gd), holmium (Ho), lanthanum (La), lutetium (Lu), neodymium (Nd), praseodymium (Pr), promethium (Pm), samarium (Sm), scandium (Sc), terbium (Tb), thulium (Tm), ytterbium (Yb), and yttrium (Y).

15. The method of claim 12, wherein providing the qubit logic circuit comprises:
providing a pair of outer material layers; and
providing an inner material layer disposed between the pair of outer material layers.

16. The method of claim 15,
wherein providing the outer material layers comprise providing silica (SiO₂) doped with niobium (Nb), and
wherein providing the inner material layer comprises providing SiO₂ doped with at least one of aluminum oxide (AlOₓ) and hafnium oxide (HfO_{y}), wherein x=an integer, and y=an integer.

17. The method of claim 11, further comprising:
providing a photonic crystal waveguide; and
providing a superconducting nanowire photodetector coupled with the photonic crystal waveguide, the superconducting nanowire photodetector configured to detect photons,
whereby the device is interfaceable in at least one of a single nuclear spin and a single photon by way of a confocal input/output (I/O) and detection of the photons by the superconducting nanowire photodetector.

18. The method of claim 11, wherein the device is operable in a cryo-magneto-optical probe station system.

19. The method of claim 14,
wherein providing the superconductor qubit logic circuit comprises providing one of an open-link structure and a closed-link structure, and
wherein providing the at least one rare-earth ion comprises selecting the at least one rare-earth ion depending on at least one of functionality, desired operating regime, and desired operating wavelength.

20. A method of interfacing for at least one of computing and networking by way of a multifunctional quantum node device, comprising:
providing a multifunctional quantum node device, providing the multifunctional quantum node device comprising:
providing a semiconductor vacancy qubit structure;
providing a superconductor quantum memory nanowire coupled with a spin state of the semiconductor vacancy qubit structure; and
providing a superconductor qubit logic circuit coupled with the superconductor quantum memory nanowire and the semiconductor vacancy qubit structure,
whereby the device is a hybrid device operable as an interface for at least one of computing and quantum-entangled networking; and
coupling the multifunctional quantum node device with at least one of a processor, a memory device, and a network.
